(19) United States
(12) Patent Application Publication
(10) Pub. No.: US 2024/0258139 A1
(43) Pub. Date: Aug. 1, 2024

(54) WAFER TEMPERATURE CONTROL DEVICE, WAFER TEMPERATURE CONTROL METHOD AND WAFER TEMPERATURE CONTROL PROGRAM

(71) Applicant: HORIBA STEC, Co., Ltd., Kyoto-shi (JP)

(72) Inventors: Daisuke HAYASHI, Kyoto-shi (JP); Kotaro TAKIJIRI, Kyoto-shi (JP)

(21) Appl. No.: 18/423,244

(22) Filed: Jan. 25, 2024

(30) Foreign Application Priority Data
Jan. 27, 2023 (JP) 2023-011118

(51) Int. Cl. H01L 21/67; H01L 21/66

(52) U.S. Cl. CPC H01L 21/67248; H01L 22/12

(57) ABSTRACT

A wafer temperature control device controls a temperature of a wafer by adjusting pressure of a gas, predicts future a temperature, and controls the temperature to a target temperature. The wafer is placed on a temperature adjusted plate and the gas is supplied between the plate and the wafer to control the wafer temperature. The control device comprises a pressure regulator that adjusts the pressure of the gas, a sensor that measures the vicinity temperature of the wafer, and a pressure control unit that controls a pressure operation amount input to the pressure regulator by model predictive control based on the vicinity temperature and target temperature of the wafer, and the pressure control unit uses a model, in which a heat transfer coefficient between the plate and the wafer is a variable obtained from the pressure of the gas, as a predictive model for the model predictive control.

### BACKGROUND OF THE INVENTION

### 1. Technical Field

The present application claims priority to Japan Patent Application No. 2023-11118 filed Jan. 27, 2023, which is incorporated herein by reference in its entirety.

### 2. Description of the Related Art

This invention relates to a wafer temperature control device, a wafer temperature control method and a wafer temperature control program.

Conventionally, in semiconductor manufacturing processes such as, for example, deposition process, the wafer as an object to be processed is placed on a plate such as an electrostatic chuck. The temperature of the plate such as the electrostatic chuck is adjusted to control the temperature of the wafer to a predetermined target temperature.

The plate on which the wafer is placed is arranged in a low-pressure environment such as a vacuum or the like. Therefore, as shown in the patent document 1, a heat transfer gas such as a helium gas is considered to be supplied between the plate and the wafer in order to promote heat transfer from the temperature adjusted plate to the wafer.

Since the heat transfer coefficient differs depending on the pressure of the heat transfer gas supplied between the plate and the wafer, it is necessary to adjust the pressure of the heat transfer gas.

However, even if the pressure of the heat transfer gas is adjusted, it is difficult to control the temperature of the wafer itself placed on the plate due to various technical limitations.

### PRIOR ART DOCUMENTS

### [Patent Document]

[Patent document 1] Patent No. 4034344

### SUMMARY OF THE INVENTION

On the other hand, the present claimed inventor is considering applying model predictive control (MPC: Model Predictive Control) by modeling the heat transfer from the temperature adjusted plate to the wafer in the above-mentioned configuration. For the state equation of the model predictive control, in order to simplify the model and reduce the (numerical burden?), it is considered to use constants obtained from physical property for the coefficient matrix of the state vector (A matrix) and the coefficient matrix of the input vector (B matrix).

However, as mentioned above, since the heat transfer coefficient varies with the pressure of the gas supplied between the plate and the wafer, if a constant (a fixed heat transfer coefficient) is used for the coefficient matrix (A matrix) of the state vector in a model wherein the heat transfer coefficient changes with time, it becomes difficult to accurately control the temperature of the wafer to the target temperature.

The present claimed invention was made to solve the above-mentioned problem and an object of this invention is to predict the future temperature of the wafer and control the temperature of the wafer to the target temperature for a device that controls the temperature of the wafer by adjusting the gas pressure.

More specifically, a wafer temperature control device in accordance with this invention is a wafer temperature control device in which a wafer is placed on a temperature adjusted plate and that controls a temperature of the wafer by supplying a gas between the plate and the wafer, and is characterized by comprising a pressure regulator for adjusting the pressure of the gas, a vicinity temperature sensor for measuring a vicinity temperature of the wafer, and a pressure control unit for controlling a pressure operation amount input to the pressure regulator by means of model predictive control based on the vicinity temperature measured by the vicinity temperature sensor and a target temperature of the wafer, and the pressure control unit uses a model in which a heat transfer coefficient between the plate and the wafer is a variable obtained from the pressure of the gas as a predictive model for the model predictive control.

In accordance with the wafer temperature control device having the above-mentioned arrangement, since the model in which the heat transfer coefficient between the plate and the wafer is the variable obtained from the pressure of the gas is used as the predictive model for the model predictive control, it is possible to predict the future temperature of the wafer and to control the wafer temperature to the target temperature.

The vicinity temperature is the temperature of a member or space within a predetermined distance from the wafer and includes temperatures wherein it is possible to construct a temperature model indicating a relationship between the temperature of the wafer and the vicinity temperature. In addition, the vicinity temperature includes the temperature of a member that makes in direct contact with the wafer, the temperature of a space or a gas in which an interface exists with the wafer, or the temperature of a member that exists through a gap of several μm with respect to the wafer. Furthermore, the vicinity temperature may include the temperature of a member wherein conduction or transfer of heat can occur by at least one of conduction, convection, and radiation to and from the wafer.

In order to predict the future temperature of the wafer accurately, it is preferable that the heat transfer coefficient used in the predictive model has a nonlinear or linear relationship depending on the pressure of the gas.

As a concrete embodiment of the pressure control unit conceived is that the pressure control unit controls the pressure operation amount using a state equation in which the pressure of the gas is included as a parameter in a coefficient matrix of a state vector in the model predictive control.

As a concrete embodiment of the pressure control unit conceived is that the pressure control unit calculates the coefficient matrix every time a prediction trajectory regarding the temperature of the wafer in the model predictive control is calculated and calculates the prediction trajectory using the calculated coefficient matrix.

Concretely, it is conceived that the pressure control unit calculates the coefficient matrix using the pressure operation amount input to the pressure regulator or the pressure adjusted by the pressure regulator every time the prediction trajectory is calculated.

It is conceived that the pressure control unit determines the pressure operation amount so as to minimize an evaluation function regarding a deviation between a reference trajectory relating to the temperature of the wafer and the prediction trajectory relating to the temperature of the wafer in the model predictive control. It is conceived that the pressure control unit uses a weighted least squares method as the evaluation function. As mentioned, iterative calculation becomes unnecessary and an amount of calculation can be reduced by using the weighted least squared method is used as the evaluation function.

The model predictive control of the present claimed invention can be preferably used in the plate in which a plurality of zones wherein the target temperatures of the wafer differ from each other are set.

In addition, a wafer temperature control method in accordance with this invention is a wafer temperature control method for controlling a temperature of a wafer by placing the wafer on a temperature adjusted plate and supplying a gas between the plate and the wafer, and the pressure of the gas is adjusted by a pressure regulator, a vicinity temperature of the wafer is measured by a vicinity temperature sensor, and a pressure operation amount, which is input to the pressure regulator by means of model predictive control, is controlled based on the vicinity temperature measured by the vicinity temperature sensor and a target temperature of the wafer, and is characterized by that a model, in which a heat transfer coefficient between the plate and the wafer is a variable obtained from the pressure of the gas, is used as a predictive model for the model predictive control.

Furthermore, a wafer temperature control program in accordance with this invention is a wafer temperature control program that is used in a wafer temperature control device in which a wafer is placed on a temperature adjusted plate, a gas is supplied between the plate and the wafer to control the temperature of the wafer, and comprises a pressure regulator to adjust the pressure of the gas, and a vicinity temperature sensor to measure the vicinity temperature of the wafer, and is characterized by providing a computer with a function as a pressure control unit that controls a pressure operation amount input to the pressure regulator by means of model predictive control based on the vicinity temperature measured by the vicinity temperature sensor and a target temperature of the wafer, and the pressure control unit uses a model, in which a heat transfer coefficient between the plate and the wafer is a variable obtained from the pressure of the gas, as a predictive model for the model predictive control.

The wafer temperature control program may be delivered electronically or recorded on a program recording medium such as a CD, a DVD or a flash memory.

### Effects of the Invention

In accordance with this invention, it becomes possible for the wafer temperature control device in which the temperature of the wafer is controlled by adjusting the pressure of the gas to predict future temperatures of the wafer and control the temperatures of the wafer to target temperatures.

### BRIEF DESCRIPTION OF THE DRAWINGS

FIG. 1 is a perspective view schematically showing a configuration of a wafer temperature control device in accordance with one embodiment of this invention;

FIG. 2 is a view showing a relationship between pressure of the heat transfer gas supplied between the wafer and the suction plate and the heat transfer coefficient between the wafer and the suction plate;

FIG. 3 is a view showing a mechanism of model prediction control of this embodiment;

FIG. 4 is a view showing a control target model used for model prediction control of this embodiment;

FIG. 5 is a view showing a reference trajectory and a prediction trajectory wherein two zones that differ each other are indicated without discriminating two zones in the mode prediction control in this embodiment;

FIG. 6 is a view showing a state equation and a reference trajectory of the model prediction control in this embodiment;

FIG. 7 is a view showing a prediction value by a free response, a prediction value and a prediction trajectory by a step response in this embodiment;

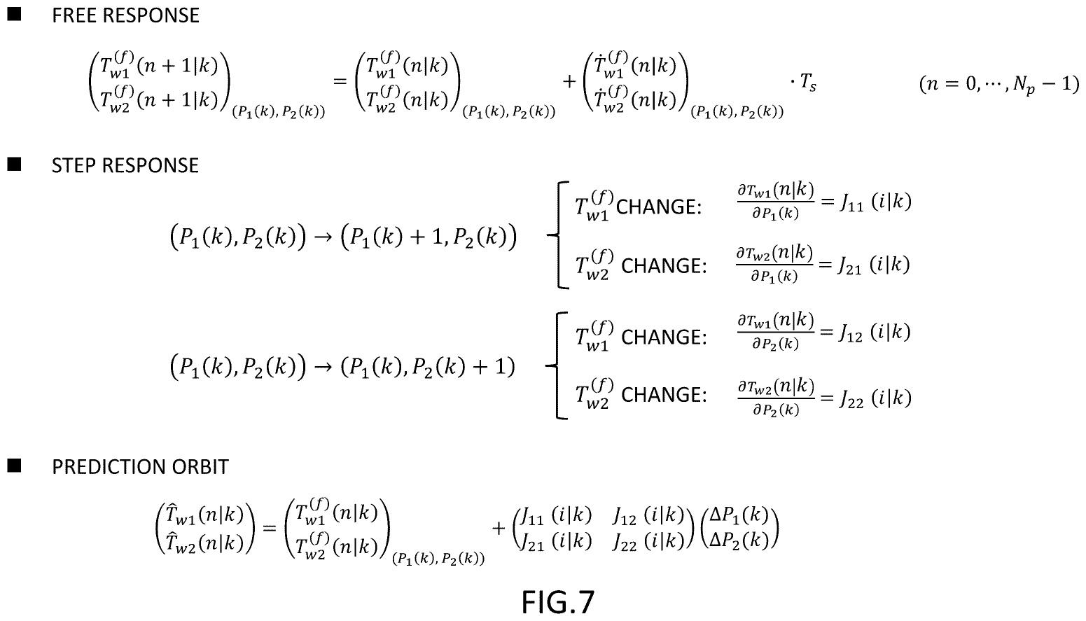

FIG. 8 is a view showing an evaluation function of the model prediction control in this embodiment; and

FIG. 9 is a view showing simulation results in case that the temperature of the wafer is controlled using the wafer temperature control device in this embodiment and in case that the temperature of the wafer is controlled by fixing the pressure of the coefficient matrix (A matrix) at the initial pressure in the model predictive control (comparative example).

### DETAILED DESCRIPTION

### One Embodiment of this Invention

One embodiment of the wafer temperature control device of the present claimed invention is described below with reference to drawings.

All of the figures shown below are schematically depicted by appropriately omitting or exaggerating for the sake of clarity. Identical components will be marked with identical symbols, and explanations will be omitted as appropriate.

### 1. A Basic Configuration of the Wafer Temperature Control Device

The wafer temperature control device 100 of this embodiment is used, for example, in a semiconductor manufacturing system that performs semiconductor manufacturing processes such as film deposition processing, and is configured, for example, to electrostatically chuck a backside of a wafer (W) in a vacuum chamber.

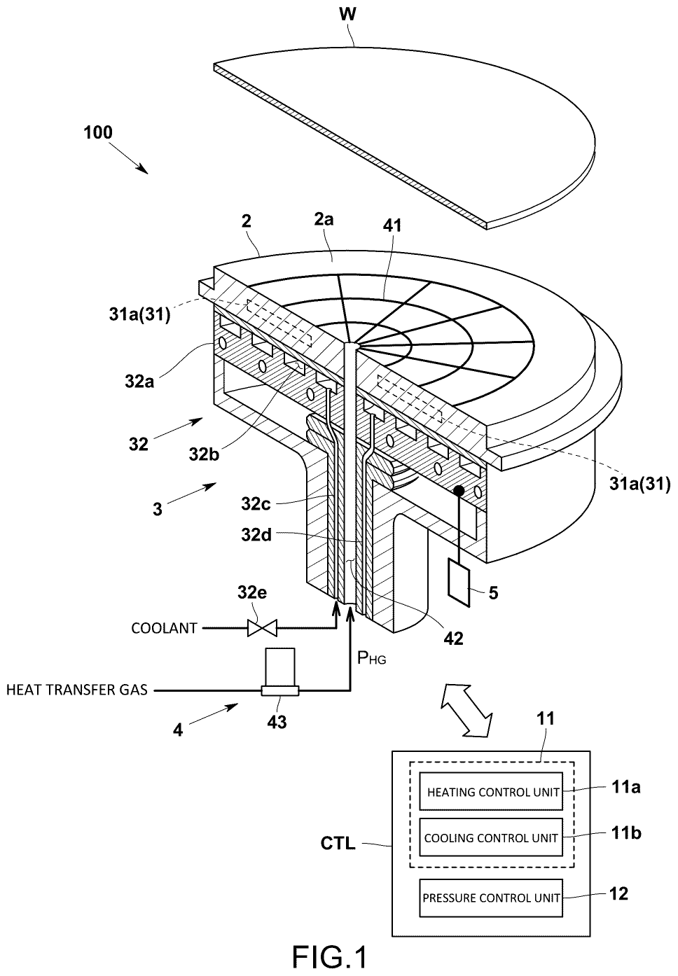

Concretely, the wafer temperature control device 100 comprises a suction plate 2 on whose upper surface the wafer (W) is placed and a temperature regulator 3 that adjusts temperature of the suction plate 2, as shown in FIG. 1.

The suction plate 2 constitutes a so-called electrostatic chuck that holds the wafer (W) by an electrostatic suction force. The suction plate 2 in this embodiment is a roughly disc-shaped ceramic plate, and its upper surface becomes a suction surface 2a that sucks the wafer (W). Inside the suction plate 2 provided is an electrostatic electrode (not shown in drawings) for generating the electrostatic force between the suction plate 2 and the wafer (W).

The temperature regulator 3 adjusts the temperature of the suction plate 2 to a predetermined temperature and has a heater 31 for heating the suction plate 2 and a cooler 32 for cooling the suction plate 2. The temperature regulator 3 may be configured without the heater 31.

The heater 31 is arranged inside the suction plate 2 and has a plurality of heater electrodes 31a for heating the suction plate 2. A plurality of the heater electrodes 31a are so configured that the power supplied by a heating control unit 11a of a control unit (CTL) and are independently controlled according to a heating operation amount set by a user.

The cooler 32 is arranged in contact with a bottom surface of the suction plate 2 and comprises a roughly disc-shaped base plate 32a and a cooling flow channel 32b formed in the base plate 32a.

The cooling flow channel 32b is formed in an inside of the base plate 32a in a spiral shape in plane view. The cooling flow channel 32b is connected to an inlet flow channel 32c and an outlet flow channel 32d, which are connected to a cooling source such as, for example, a chiller (not shown in drawings). In addition, a control valve 32e for controlling a coolant flow rate is arranged in a flow channel that is connected to the cooling flow channel 32b and a valve opening degree is controlled by a cooling control unit 11b of the control unit (CTL).

In addition, the wafer temperature control device 100 of this embodiment comprises a gas supply mechanism 4 for supplying a gas (hereinafter “heat transfer gas”) that transfers heat transfer, such as a helium gas or an argon gas between the suction plate 2 and the wafer (W).

The gas supply mechanism 4 supplies the heat transfer gas at a predetermined pressure between the suction surface 2a of the suction plate 2 and the backside of the sucked wafer (W).

Concretely, the gas supply mechanism 4 has a gas distribution groove 41 formed on the suction surface 2a of the suction plate 2, a gas supply channel 42 that supplies the heat transfer gas to the gas distribution groove 41, and a pressure regulator 43 that adjusts the pressure of the heat transfer gas supplied to the gas distribution groove 41. The heat transfer gas supplied to the gas distribution groove 41 flows from the gas distribution groove 41 to a space between the suction surface 2a of the suction plate 2 and the backside of the sucked wafer (W).

The gas distribution groove 41 has a plurality of linear grooves formed radially from a central axis of the suction plate 2 and a plurality of circular grooves formed concentrically from the central axis of the suction plate 2. In addition, the gas supply channel 42 is formed along the central axis of the suction plate 2 and is connected to a heat transfer gas source (not shown in drawings).

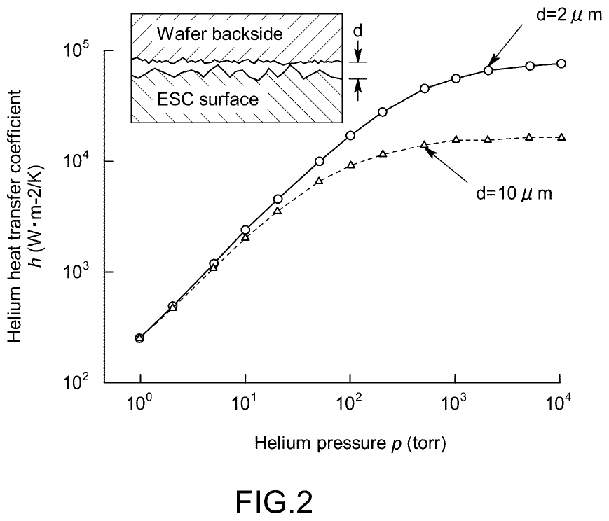

In addition, the pressure regulator 43 can change a heat transfer rate (a heat transfer coefficient between the wafer (W) and the suction plate 2) from the suction plate 2 to the wafer (W) by adjusting the pressure of the heat transfer gas. FIG. 2 shows a relationship between the pressure of the heat transfer gas supplied to a space between the wafer (W) and the suction plate 2 and the heat transfer coefficient between the wafer (W) and the suction plate 2. The heat transfer coefficient in this embodiment has a non-linear relationship depending on the pressure of the heat transfer gas, however, it may also have a linear relationship.

Concretely, the pressure regulator 43 has a pressure sensor and a pressure control valve, and the valve opening degree is controlled by a pressure control unit 12 of the control unit (CTL).

In addition, the wafer temperature control device 100 comprises a vicinity temperature sensor 5 that measures the temperature in the vicinity of the wafer (W). The vicinity temperature sensor 5 is arranged on a back surface side of the base plate 32a and measures the temperature of the base plate 32a as the temperature in the vicinity of the wafer (W). The vicinity temperature sensor 5 in this embodiment is, for example, an infrared sensor such as a radiation thermometer. The vicinity temperature sensor 5 may also be used to measure the temperature of the suction plate 2 as the temperature in the vicinity of the wafer (W).

### 2. Wafer Temperature Control System

Furthermore, the wafer temperature control device 100 comprises the control unit (CTL) that controls the operation of at least the temperature regulator 3 and the pressure regulator 43.

The control unit (CTL) is a so-called computer comprising a CPU, a memory, an A/D converter, a D/A converter, and various input/output devices. The control unit (CTL) produces functions as the temperature control unit 11 that controls the operation of the temperature regulator 3 and the pressure control unit 12 that controls the operation of the pressure regulator 43 by executing wafer temperature control programs stored in the memory and making the various devices work together.

The temperature control unit 11 in this embodiment has the heating control unit 11a and the cooling control unit 11b and supplies fixed electric power to each of the heater electrodes 31a of the heater 31 by the heating control unit 11a and controls the valve opening degree of the control valve 32e of the cooler 32 to be constant by the cooling control unit 11b. In other words, the temperature control unit 11 fixes a heating operation amounts of the heater 31 and a cooling operation amount of the cooler 32 during the operation and controls the temperature adjustment amount per unit time by the temperature regulator 3 to be constant. In the heating control unit 11a and the cooling control unit 11b, since the heating operation amount and the cooling operation amount are not variables for other physical property values (for example, a heat transfer coefficient or the like) and are not included in the coefficient matrix (A matrix) to be described later, the predictive model control performed in the pressure control unit 12 to be described later is not performed.

The pressure control unit 12 controls the pressure regulator 43 that adjusts the pressure (P_{HG}) of the heat transfer gas by means of the model predictive control based on the vicinity surface temperature measured by the vicinity surface temperature sensor 5 and the target temperature of the wafer (W).

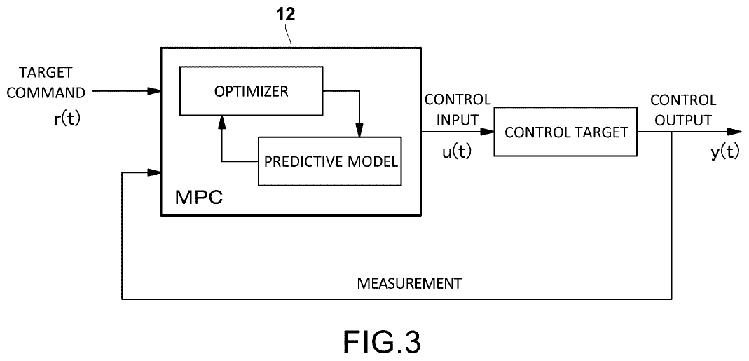

In this embodiment, the model predictive control is a control method that performs optimization while predicting a future response at each time, as shown in FIG. 3, and predicts future behavior over a certain finite interval from a current time of an object to be controlled by having a predictive model (an object model to be controlled) inside the pressure control unit 12. In FIG. 3, a target command (r(t)) is the target temperature of the wafer (W), a control input (u(t)) is the pressure operation amount input to the pressure regulator 43, and a control output (y(t)) is the vicinity temperature measured by the vicinity temperature sensor 5. The vicinity temperature value measured on the object to be controlled is applied to the predictive model inside the pressure controller 12, and the new control input (u(t)) is determined to minimize a tracking error at a given time from the current time by an optimizer.

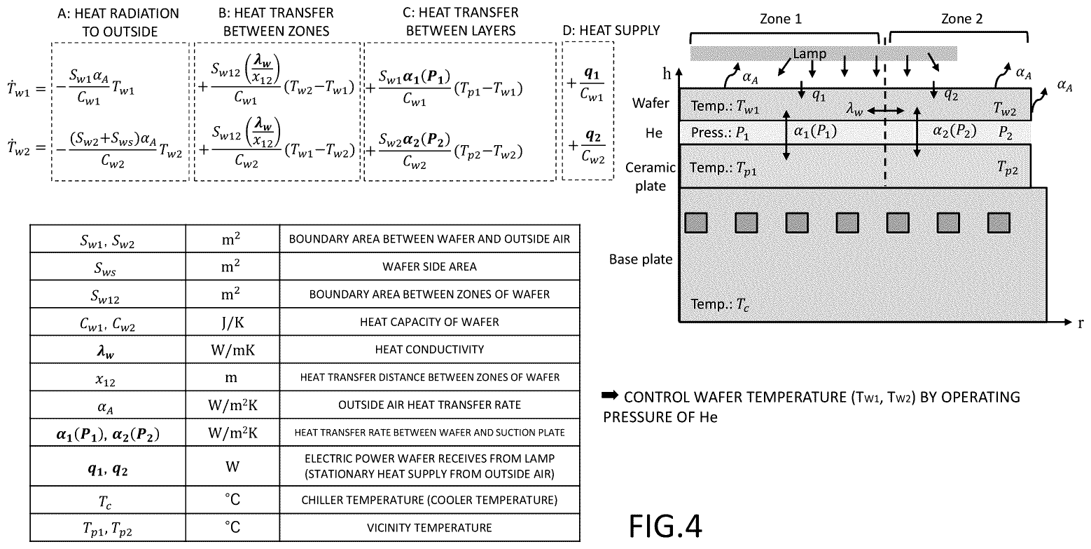

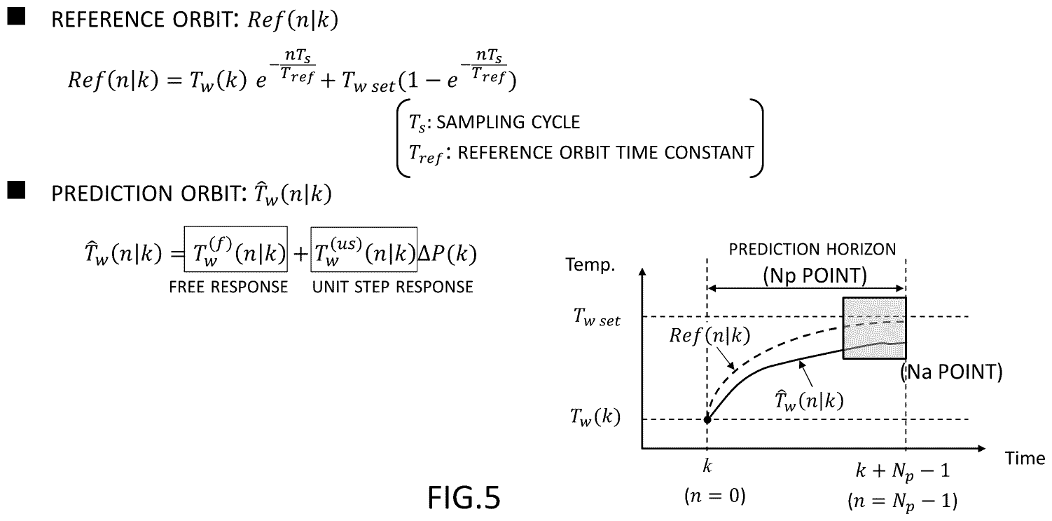

The object model to be controlled used for the model predictive control is shown in FIG. 4. The object model to be controlled has two concentric heating zones: a circular heating zone located in the center (Zone 1) and a toric heating zone located in a peripheral part (Zone 2). In the suction plate 2, the target temperature of the central heating zone is T_{W1_SET} and the target temperature of the peripheral heating zone is T_{W2_SET}. FIG. 5 shows a reference trajectory and a prediction trajectory, which are notated without distinguishing the two different zones from each other.

In the object model to be controlled shown in FIG. 4, a time variation (a variable indicating dots above T_{W1}) of the temperature (T_{W1}) of the wafer 2 in Zone 1 and a time variation (a variable indicating dots above (T_{W2})) of the temperature (T_{W2}) of the wafer 2 in Zone 2 can be indicated by term A: heat radiation to the outside, term B: heat transfer between zones, term C: heat transfer between layers and term D: heat supply. The heat radiation indicated in the term A is proportional to the fourth power of the temperature, however, since the term A itself is a small value, it is assumed to be a power of one for the sake of simplifying the calculation in this embodiment.

Concretely, as described above, the pressure control unit 12 uses a model in which the heat transfer coefficient between the suction plate 2 and the wafer (W) is a variable obtained from the pressure P_{HG} of the heat transfer gas as a predictive model (model to be controlled) for model predictive control. More concretely, the pressure control unit 12 controls the pressure operation amount input to the pressure regulator 43 by the model predictive control based on the vicinity surface temperatures T_{P1} and T_{P2} measured by the vicinity surface temperature sensor 5 and the target temperatures T_{W1_SET} and T_{W2_SET} of the wafer (W).

In this embodiment, the pressure control unit 12 controls the pressure operation amount using the state equation in which the heat transfer gas pressures P₁ and P₂ are included as parameters in the coefficient matrix (A matrix) of the state vector in the model predictive control. The reason why P₁ and P₂ are included in the coefficient matrix (A matrix) of the state vector is that the heat transfer coefficients α₁ (P₁) and α₂ (P₂) between the wafer (W) and the suction plate 2 vary with the heat transfer gas pressures P₁ and P₂.

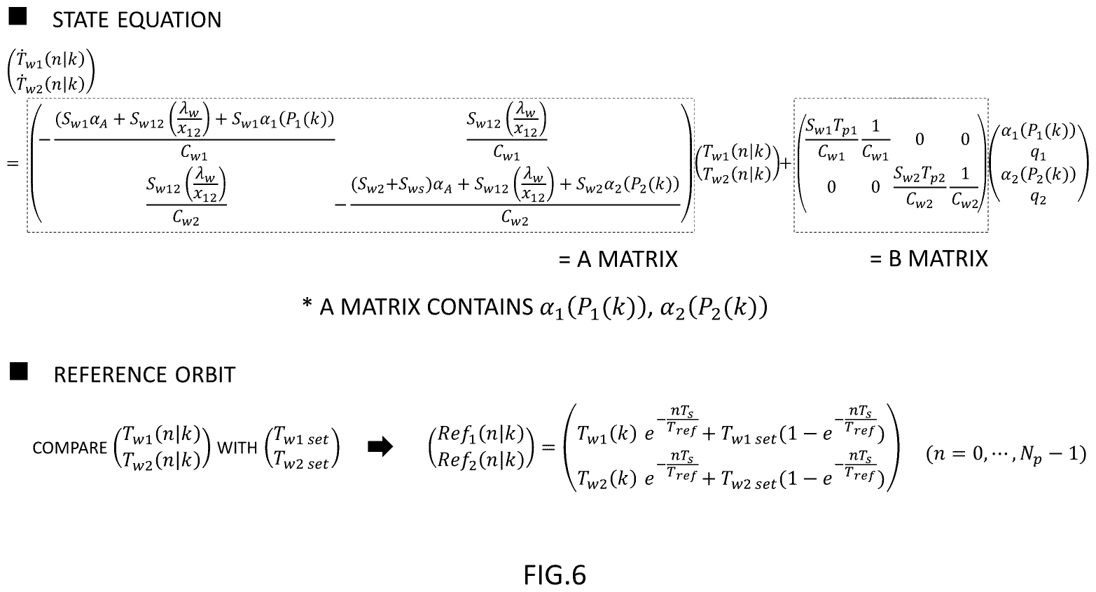

Concretely, the pressure control unit 12 uses the state equation shown in FIG. 6.

In this state equation, the coefficient matrix (A matrix) hanging on the state vector is a matrix indicating the heat conductivity and the heat capacity for each divided zone (zone) and includes the heat transfer coefficients α₁ (P₁) and α₂ (P₂) between wafer (W) and the suction plate 2 obtained from the heat transfer gas pressures P₁ and P₂. In addition, the coefficient matrix (B matrix) hanging on the input vector in the state equation is a matrix indicating the heat transfer coefficients α₁ (P₁) and α₂ (P₂) between the wafer (W) and the suction plate 2 and the coefficients that convert the steady-state heat supplies q₁ and q₂ from the outside air to temperature change. Furthermore, the reference trajectory in the model predictive control indicates an ideal trajectory that exponentially approaches the set temperature from the temperature at the current time and is shown in FIG. 6.

The pressure control unit 12 calculates the coefficient matrix (A matrix) every time the prediction trajectory regarding the temperature of the wafer (W) is calculated in the model predictive control, and the next prediction trajectory is calculated using the coefficient matrix (A matrix) updated by the calculation.

Concretely, the pressure control unit 12 calculates the prediction trajectory obtained from the state equation, as shown in FIG. 5 and FIG. 6, and concretely, calculates the prediction trajectory by the use of the predicted value by the free response and the predicted value by the step response.

The predicted value by the free response indicates the trajectory after Np steps from the current (time k) with keeping the inputs P₁(k) and P₂(k).

The predicted value by the step response indicates the difference (change) between the temperature of the trajectory for the future Np step and the current temperatures T_{W1}(k) and T_{W2}(k) in case that the input P₁(k) is P₁(k)+1 and in case that the input P₂(k) is P₂(k)+1.

In this embodiment, since the inputs P₁(k) and P₂(k) are updated sequentially, it is necessary to calculate and obtain the inputs P₁(k) and P₂(k) every time. The inputs P₁(k) and P₂(k) used for the predicted value by the step response are the pressure operation amount input to the pressure regulator 43 or the pressure regulated by the pressure regulator 43.

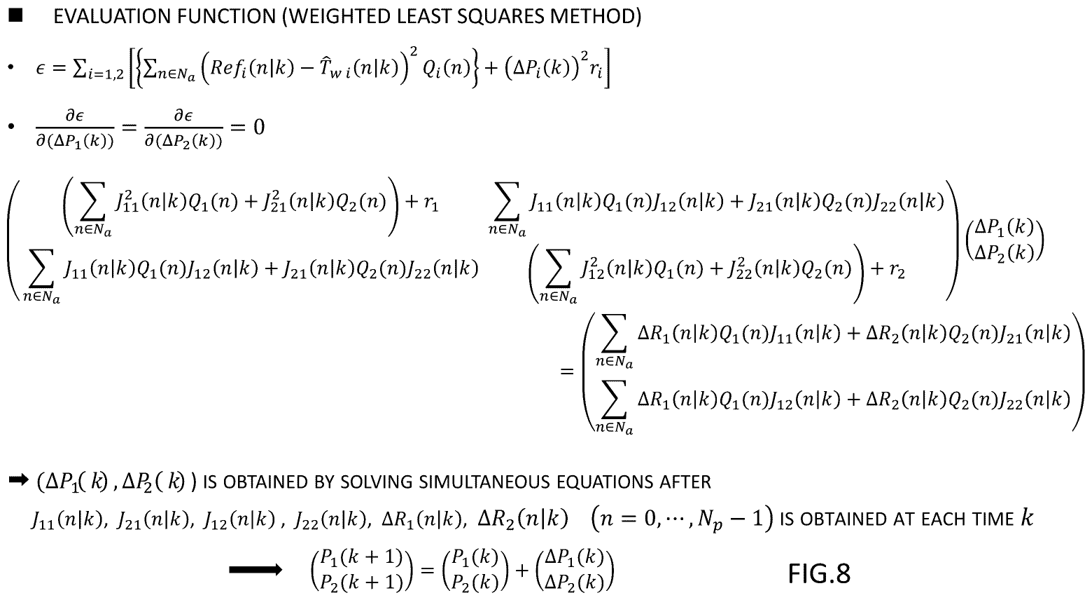

The pressure control unit 12 determines, as shown in FIG. 8, the pressure operation amount so as to minimize the evaluation function using the weighted least squares method regarding the deviation between the reference trajectory regarding the temperature of the wafer (W) and the prediction trajectory regarding the temperature of the wafer (W) in the model predictive control. In order to prevent hunting from occurring in the evaluation function, terms r₁ and r₂ to reduce the pressure are added, and the terms r₁ and r₂ are made as small as possible. By using the weighted least squares method as the evaluation function, it becomes unnecessary to conduct iterative calculations so that an amount of calculation can be reduced. In case that it is not possible to solve the evaluation function analytically due to constraints, a shooting method, a gradient descent method, a Newton method, or other exploratory methods may be used as the evaluation function.

### 3. Simulation Results

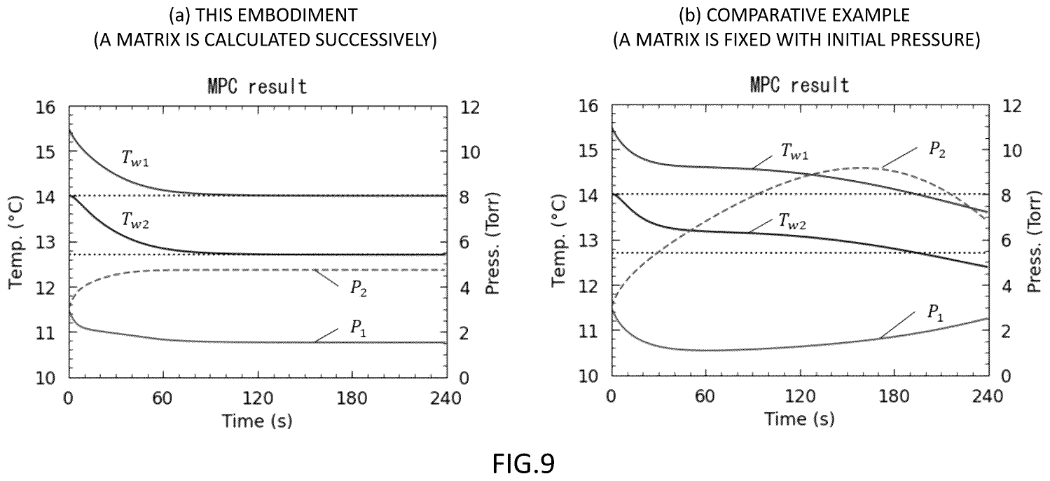

Next, FIG. 9 shows simulation results in case that the temperature of the wafer (W) is controlled using the wafer temperature control device 100 of this embodiment and in case that the temperature of the wafer (W) is controlled by fixing the pressure of the coefficient matrix (A matrix) at the initial pressure in the model predictive control (comparative example).

In either simulation, a target temperature (° C.) is (T_{W1_SET}, T_{W2} SET)=(14.0, 12.7), an initial temperature (° C.) is (T_{W1}, T_{W2})=(15.5, 14.0) and an initial pressure is (P₁, P₂)=(3.0, 3.0). In addition, a sampling cycle (T_{S}) is 1 second, a reference trajectory time constant (T_{ref}) is 15 seconds, a number of predicted horizon points (Np) is 30, and a number of coincidence points (Na) is 15.

As can be seen from FIG. 9(a), in case that the temperature of the wafer (W) is controlled using the wafer temperature control device 100 of this embodiment, the temperatures (T_{W1}) and (T_{W2}) of the wafer (W) can be accurately controlled to the target temperatures (T_{W1_SET}) and (T_{W2_SET}). On the other hand, as can be seen from FIG. 9(b), in case that the temperature of the wafer (W) is controlled with fixing the pressure of the coefficient matrix (A matrix) at the initial pressure in the model predictive control, the temperatures (TW) and (T_{W2}) of the wafer (W) cannot be accurately controlled to the target temperatures (T_{W1_SET}) and (T_{W2_SET}).

### 4. Effects of this Embodiment

In accordance with the wafer temperature control device 100 in this embodiment, since the model in which the heat transfer coefficient, which is obtained from the pressure of the heat transfer gas, between the suction plate 2 and the wafer (W) is used as a variable as the predictive model for model predictive control, it is possible to predict the future temperature of the wafer (W) so that the temperature of the wafer (W) can be controlled at the target temperature. Concretely, since the pressure operation amount is controlled using the state equation in which the heat transfer gas pressure is included as a parameter in the coefficient matrix (A matrix) of the state vector in the model predictive control, the temperature of the wafer can be accurately controlled to the target temperature.

### 5. Other Embodiments

For example, in the suction plate 2 of the above-mentioned embodiment, a plurality of zones where the target temperature of the wafer (W) differs from each other are set by varying the pressure of the heat transfer gas on the surface of the suction plate 2, however, a single target temperature may be set for the entire suction plate 2 without varying the heat transfer gas pressure on the surface of the suction plate 2.

In addition, the heater 31 of the above-mentioned embodiment can form a temperature distribution on the suction plate 2 by means of a plurality of the heater electrodes 31a. For example, the heater 31 can vary the amount of heating between the center and a periphery of the suction plate 2. Furthermore, the heater 31 can vary the amount of heating also between a large zone forming a roughly C-shape and a remaining small zone in the periphery. More specifically, three heating zones are set up on the suction plate 2, and this creates a temperature distribution on the suction plate 2. In addition, the cooler 32 may also be configured to form three cooling zones on the surface of the base plate 32a, corresponding to the three heating zones of the suction plate 2. Various other setting methods are conceivable, such as radially dividing the outer circumference parts to set multiple heating zones.

The heating or cooling zones of the wafer (W) and suction plate 2 are not limited to three divided zones, however, may be further divided into a plurality of zones or two zones. In addition, whole of the wafer (W) or the suction plate 2 may be treated as a single temperature without setting any zones.

In addition, the suction plate 2 may not have a suction function and may simply be a plate on which the wafer (W) is placed.

The configuration of the cooler or the heater is not limited to those described above. For example, the cooler may be configured by making use of a Peltier element or the like, and the heater may not be limited to the heater electrode, however, may be configured to heat the wafer by light irradiation, or the wafer may be heated by plasma.

The locations where the vicinity temperature sensor measures are not limited to the above-mentioned locations, however, may be other locations. More specifically, the temperature that may have some correlation or relationship with the temperature of the wafer may be measured as the vicinity temperature. In addition, the vicinity temperature sensor is not limited to the infrared temperature sensor, however, may be, for example, a thermocouple installed in the plate.

In addition, various other variations and combinations of embodiments may be made without departing from a spirit of the invention.

### DESCRIPTION OF CODES

100 . . . wafer temperature control device
W . . . wafer
2 . . . suction plate (plate)
3 . . . temperature regulator
43 . . . pressure regulator
5 . . . vicinity temperature sensor
12 . . . pressure control unit

1. A wafer temperature control device in which a wafer is placed on a temperature adjusted plate and that controls a temperature of the wafer by supplying a gas between the plate and the wafer, comprising:
a pressure regulator for adjusting the pressure of the gas;
a vicinity temperature sensor for measuring a vicinity temperature of the wafer; and
a pressure control unit for controlling a pressure operation amount input to the pressure regulator by means of model predictive control based on the vicinity temperature measured by the vicinity temperature sensor and a target temperature of the wafer;
wherein the pressure control unit uses a model in which a heat transfer coefficient between the plate and the wafer is a variable obtained from the pressure of the gas as a predictive model for the model predictive control.

2. The wafer temperature control device according to claim 1, wherein the heat transfer coefficient used in the predictive model has a nonlinear or linear relationship depending on the pressure of the gas.

3. The wafer temperature control device according to claim 1, wherein the pressure control unit controls the pressure operation amount using a state equation in which the pressure of the gas is included as a parameter in a coefficient matrix of a state vector in the model predictive control.

4. The wafer temperature control device according to claim 3, wherein the pressure control unit calculates the coefficient matrix every time a prediction trajectory regarding the temperature of the wafer in the model predictive control is calculated and calculates the prediction trajectory using the calculated coefficient matrix.

5. The wafer temperature control device according to claim 4, wherein the pressure control unit calculates the coefficient matrix using the pressure operation amount input to the pressure regulator or the pressure adjusted by the pressure regulator every time the prediction trajectory is calculated.

6. The wafer temperature control device according to claim 1, wherein the pressure control unit determines the pressure operation amount so as to minimize an evaluation function regarding a deviation between a reference trajectory relating to the temperature of the wafer and the prediction trajectory relating to the temperature of the wafer in the model predictive control.

7. The wafer temperature control device according to claim 6, wherein the pressure control unit uses a weighted least squares method as the evaluation function.

8. The wafer temperature control device according to claim 1, wherein a plurality of zones wherein the target temperatures of the wafer differ from each other are set on the plate.

9. A wafer temperature control method for controlling a temperature of a wafer by placing the wafer on a temperature adjusted plate and supplying a gas between the plate and the wafer, wherein
pressure of the gas is adjusted by a pressure regulator,
a vicinity temperature of the wafer is measured by a vicinity temperature sensor, and
a pressure operation amount, which is input to the pressure regulator by means of model predictive control, is controlled based on the vicinity temperature measured by the vicinity temperature sensor and a target temperature of the wafer, wherein
a model, in which a heat transfer coefficient between the plate and the wafer is a variable obtained from the pressure of the gas, is used as a predictive model for the model predictive control.

10. A non-transitory computer-readable medium storing a wafer temperature control program used in a wafer temperature control device in which a wafer is placed on a temperature adjusted plate, a gas is supplied between the plate and the wafer to control the temperature of the wafer, and which comprises a pressure regulator to adjust the pressure of the gas, and a vicinity temperature sensor to measure the vicinity temperature of the wafer, the wafer temperature control program being executable to cause a computer to:
function as a pressure control unit that controls a pressure operation amount which is input to the pressure regulator by means of model predictive control based on the vicinity temperature measured by the vicinity temperature sensor and a target temperature of the wafer, wherein
the pressure control unit uses a model, in which a heat transfer coefficient between the plate and the wafer is a variable obtained from the pressure of the gas, as a predictive model for the model predictive control.
